(19) United States
(12) Patent Application Publication
(10) Pub. No.: US 2012/0126865 A1
(43) Pub. Date: May 24, 2012

(54) CLOCK REGENERATION CIRCUIT

(75) Inventor: Kouichi Yamaguchi, Tokyo (JP)

(73) Assignee: NEC Corporation, Tokyo (JP)

(21) Appl. No.: 13/388,894

(22) PCT Filed: Aug. 4, 2009
(86) PCT No.: PCT/JP2009/064097

§ 371 Date: Feb. 3, 2012

(51) Int. Cl. H03L 7/06

(52) U.S. Cl. 327/146; 327/155

(57) ABSTRACT

A clock regeneration circuit according to an exemplary embodiment of the present invention is characterized in that a phase comparison result of serial data being inputted and a clock signal is shaped with use of the clock signal or another clock signal having a predetermined phase difference from the clock signal, and a phase of the clock signal is controlled with use of the shaped phase comparison result.

### TECHNICAL FIELD

The present invention relates to a clock regeneration circuit used in a high-speed serial communication.

### BACKGROUND ART

In order to accurately receive a waveform of data being inputted, a clock regeneration circuit for adjusting a clock signal into the optimal timing for the data waveform is used in a receiving circuit for a high-speed serial communication. In a clock regeneration circuit, the phase of a waveform of data being inputted is compared with the phase of the clock signal. The timing of the clock is adjusted based upon the results. Particularly, in a high-speed serial communication, a clock regeneration circuit using a binary phase comparator for digitally outputting phase comparison results has widely been used.

A clock regeneration circuit illustrated at page 1573 of volume 39 of IEEE Journal of Solid-State Circuits (Jri Lee, K. Kundert, and B. Razavi, “Analysis and modeling of bang-bang clock and data recovery circuits,” Solid-State Circuits, IEEE Journal of, vol. 39, 2004, pp. 1571-1580.) regenerates a clock with use of a binary phase comparator (Alexander type) that operates with a clock signal having the same rate as a rate of input data. Furthermore, a clock regeneration circuit illustrated at page 1784 of volume 37 of IEEE Journal of Solid-State Circuits (J. E. Rogers and J. R. Long, “A 10-Gb/s CDR/DEMUX with LC delay line VCO in 0.18-/spl mu/m CMOS,” Solid-State Circuits, IEEE Journal of, vol. 37, 2002, pp. 1781-1789.) performs a binary phase comparison with two pairs of clocks having a frequency that is half of a rate of input data and having phases different from each other by 90 degrees (4-phase clocks).

### DISCLOSURE OF THE INVENTION

### Problem(s) to be Solved by the Invention

However, the former clock regeneration circuit needs a clock having the same rate as a data rate. Therefore, as the communication becomes faster, the circuit becomes difficult to operate. Meanwhile, with the latter configuration using 4-phase clocks, the frequency of a clock is reduced to ½ as compared to the former clock regeneration circuit. Logical operations need to be performed on two pairs of phase comparison results generated by the 4-phase clocks. Specifically, two pairs of phase comparison results are subjected to an OR operation, and the data are held by flip-flops. Thus, a pair of phase comparison results (Early/Late) is obtained. Therefore, a delay occurs until the phase comparison results are reflected on the actual clock control. Accordingly, there is a problem that the performance of the feedback control is deteriorated.

An exemplary object of the present invention is to provide a clock regeneration circuit that is operable at a high speed with use of multi-phase clocks and does not deteriorate the performance of a feedback control that would be caused by logical operations of phase comparison results.

### Means to Solve the Problem

According to one exemplary aspect of the present invention, there is provided a clock regeneration circuit in which a phase comparison result of serial data being inputted and a clock signal is shaped with use of the clock signal or another clock signal having a predetermined phase difference from the clock signal, and a phase of the clock signal is controlled with use of the shaped phase comparison result.

Furthermore, according to another exemplary aspect of the present invention, there is provided a clock regeneration circuit comprising: a judgment circuit operable to sample serial data into judgment data with multi-phase clock signals; exclusive-OR circuits operable to compare judgment data that have been sampled with clock signals having adjacent phases to each other and output phase comparison results; AND circuits operable to shape the phase comparison results; a charge pump circuit operable to output a control voltage, the shaped phase comparison results being inputted to the charge pump circuit; and a voltage controlled oscillator controlled by the control voltage so as to output the multi-phase clocks.

Moreover, according to still another exemplary aspect of the present invention, there is provided a clock regeneration method including: converting serial data being inputted into judgment data that are sampled with multi-phase clock signals having predetermined phase differences; obtaining phase comparison results from an exclusive-OR operation of the judgment data that have been sampled with clock signals having adjacent phase differences; shaping the phase comparison results with use of a clock signal having a phase inverse to a multi-phase clock signal used to sample the judgment data that have been compared in the phase comparison results; and controlling a phase of the multi-phase clock signals with use of the shaped phase comparison results.

### EFFECT(S) OF THE INVENTION

According to the exemplary aspect of the present invention, there can be provided a clock regeneration circuit that is operable at a high speed with use of multi-phase clocks and does not deteriorate the performance of a loop feedback control that would be caused by logical operations of phase comparison results.

### BRIEF DESCRIPTION OF DRAWINGS

FIG. 1 is a block diagram showing a clock regeneration circuit according to an exemplary embodiment of the present invention.

FIG. 2 is a timing chart showing an operation of a pulse filter used within the clock regeneration circuit according to the exemplary embodiment of the present invention.

FIG. 3 is a timing chart showing the relationship between an invalid pulse generated within the clock regeneration circuit according to the exemplary embodiment of the present invention and clocks for filtering.

### BEST MODE(S) FOR CARRYING OUT THE INVENTION

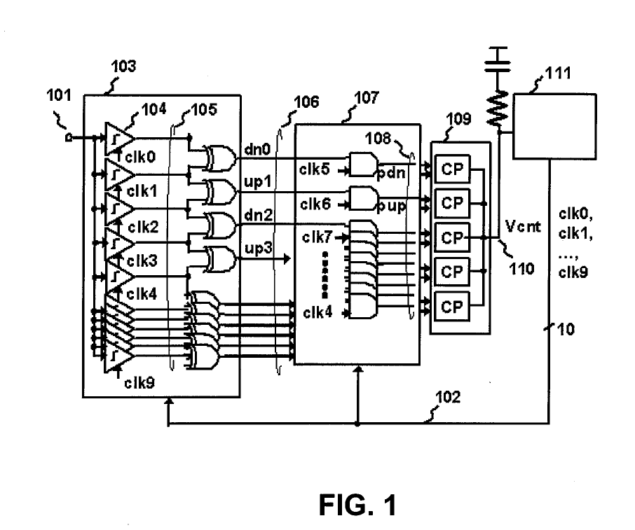

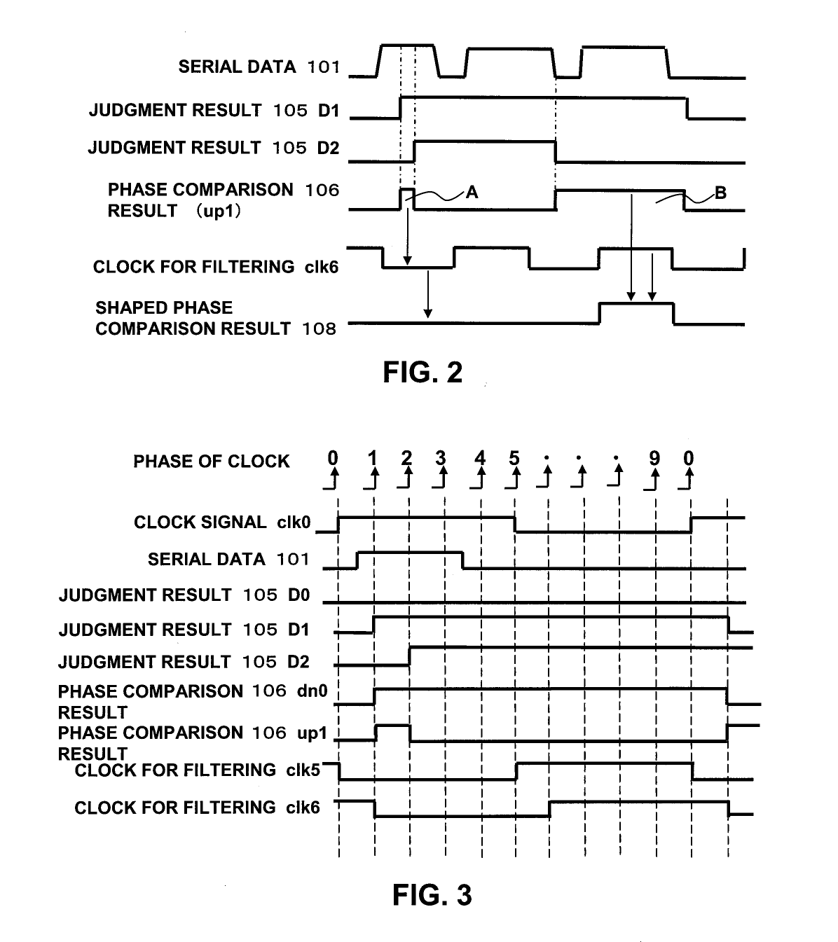

The present invention will be described below with reference to the drawings. FIG. 1 is a block diagram showing a clock regeneration circuit according to an exemplary embodiment of the present invention. FIG. 2 is a timing chart showing an operation of a pulse filter used within the clock regeneration circuit, and FIG. 3 is a timing chart showing the relationship between an invalid pulse generated within the clock regeneration circuit and clocks for filtering. A clock regeneration circuit according to the exemplary embodiment of the present invention shown in FIG. 1 includes a phase comparator circuit 103, a pulse filter 107, charge pumps 109, and a VCO (Voltage Controlled Oscillator) 111. Serial data 101 are inputted to the phase comparator circuit 103, which operates with 10-phase clocks 102. Judgment circuits 104 within the phase comparator circuit 103 sample the serial data 101 being inputted on rising edges of the 10-phase clock signals (clk0-clk9) having different phases and convert them into judgment results 105 (D0-D9). The 10-phase clock signals (clk0-clk9) are clock signal having equal phase differences. The judgment result sampled with the sample clock signal (clk0) is a judgment result 105 (D0). The number of a suffix (*) of a judgment result 105 (D*) represents a clock signal (clk*) used for sampling. Furthermore, phase comparison results 106 are represented in the order corresponding to the suffixes of the judgment results inputted into the circuits, like dn0 and up1.

Based upon those judgment results 105, exclusive-OR circuits perform a phase comparison of the serial data 101 and the 10-phase clocks 102 and output the results as phase comparison results 106 to the pulse filter 107. Two judgment results 105 sampled with clock signals having adjacent phases are inputted to each of the exclusive-OR circuits, which outputs a phase comparison result 106. For example, as shown in FIG. 1, adjacent judgment results 105 are inputted to the exclusive-OR circuits in the order of D0 and D1, D1 and D2, . . . , D9 and D0. The exclusive-OR circuits output phase comparison results 106 of dn0, up1, . . . , up9. Here, dn* of the phase comparison results is a down-control signal, which slows down the clock signal, and up* is an up-control signal, which accelerates the clock signal. Those exclusive-OR circuits output down-signals (dn) and up-signals (up) as the phase comparison results 106 alternately in the order of adjacent judgment results 105 being inputted.

The pulse filter 107 shapes the phase comparison results 106 with use of the 10-phase clocks 102 and outputs the shaped phase comparison results 108 to the subsequent charge pumps 109. A phase comparison result 106 and a filter clock signal for shaping are inputted to each of AND circuits for waveform shaping in the pulse filter 107. Each of the AND circuits for waveform shaping outputs a shaped phase comparison result 108. For example, a phase comparison result 106 (dn0) and the clock signal clk5 are inputted to an AND circuit, which outputs a shaped phase comparison result 108 (pdn). Similarly, a phase comparison result 106 (up1) and the clock signal clk6, a phase comparison result 106 (dn2) and the clock signal clk7, . . . , and a phase comparison result 106 (up9) and the clock signal clk4 are respectively inputted to the AND circuits in the order named. The AND circuits output shaped phase comparison results 108 (pup, pdn, . . . , pup), respectively. The shaped phase comparison results 108 (pup) are control signals that accelerate a clock signal, and the shaped phase comparison results 108 (pdn) are control signals that slow down a clock signal.

Combinations of phase comparison results 106 and filter clock signals inputted for shaping are not limited to specific ones. Nevertheless, the filter clock signal is preferably a clock signal having a phase inverse to a sample clock signal used for the phase comparison result 106. Specifically, clock signals used for sampling of signals (judgment results D0 and D1) that have been subjected to a phase comparison in the phase comparison result 106 (dn0) are clk0 and clk1. The clock signal clk5, which has a phase inverse to the clock signal clk0, which is one of clocks used for the judgment result D1, is used as a filter clock signal. Thus, with use of a clock signal having a phase inverse to a sample clock signal being used, removal of an invalid pulse or the like can be performed as described later. Useless operations can be lessened in the circuit. The phase comparison results 106 are inputted in the order of the phase differences of the 10-phase clock signals. Therefore, the filter clock signals clk6, . . . , clk9, clk0, . . . , clk4 are similarly inputted in the order of the phase differences.

The shaped phase comparison results 108 are outputted to the charge pumps 109 so as to control operations of the charge pumps 109. In FIG. 1, five charge pumps 109 are provided. A pair of (pup) and (pdn) are inputted as shaped phase comparison results 108 into each of the charge pumps 109. The five charge pumps 109 being provided have equivalent capability. Outputs of the five charge pumps 109 are connected in common to produce a VCO control voltage 110. Since their outputs are connected in common, the sum of the shaped phase comparison results being inputted determines the VCO control voltage 110. Therefore, any combination of the shaped phase comparison results inputted to the charge pumps 109 can be selected. Thus, the charge pumps 109 control the VCO control voltage 110 based upon the shaped phase comparison results 108, thereby controlling the phase of the 10-phase clocks 102 generated in the VCO 111.

With the configuration of the exemplary embodiment, a high-speed operation can be performed by using multi-phase clocks. It is not necessary to hold logical operation results of the phase comparison results by flip-flops. Accordingly, the VCO 111 can be controlled at a high speed.

FIG. 2 is a timing chart showing an operation of the pulse filter 107 used within the clock regeneration circuit according to the exemplary embodiment of the present invention. The timing chart shows the serial data 101, judgment results 105 (D1 and D2), a phase comparison result 106 (up1), a clock clk6 for filtering, and a shaped phase comparison result 108.

The serial data 101 are taken in at the judgment circuits 104 with the clock signals clk0-clk9 of the 10-phase clocks 102 and outputted as judgment results 105 to the exclusive-OR circuits. The judgment result 105 (D1) is a waveform obtained by judging the serial data 101 at the timing of the clock signal clk1 of the 10-phase clocks 102. The judgment result 105 (D2) is a waveform obtained by judging the serial data 101 at the timing of the clock signal clk2 of the 10-phase clocks 102. If the serial data 101 make a transition between the timing of the clock signal clk1 and the timing of the clock signal clk2, D1 and D2 of the judgment results 105 have different waveforms. An exclusive-OR operation of D1 and D2 of the judgment results 105 generates a phase comparison result 106 (up1) that is a signal for shifting the clock signal leftward (i.e., for accelerating the clock signal).

If the judgment value D1 and the judgment value D2 are the same, there is no transition of the serial data. At that time, no phase comparison result 106 is outputted in nature. However, since the judgment results D1 and D2 change at different timing, an invalid pulse A is generated in the phase comparison result 106 as shown in FIG. 2. The phase comparison result 106 (up1) shown in FIG. 2 has a pulse A and a pulse B having a high level. The pulse A does not result from a transition of the serial data, but from a phase difference between the clock signals clk1 and clk2. Thus, the pulse A is an invalid pulse A. The pulse B results from a transition of the serial data. Thus, the pulse B is the proper phase comparison result 106.

Therefore, the 10-phase clocks 102 being inputted are used as clocks for filtering in the pulse filter 107 to thereby remove such an invalid pulse A. In intervals in which the clock signal for filtering has a high level, the phase comparison result up1 is passed and is outputted to a subsequent stage. In intervals in which the clock signal for filtering has a low level, the phase comparison result up1 is blocked and is not outputted to a subsequent stage. It is preferable to use, as the clock signal for that purpose, a clock signal having a phase inverse to the clock signals used for the judgment results 105 (D1) and (D2). Specifically, the clock signals used for the judgment results 105 (D1) and (D2) are clk1 and clk2. In this example, the clock signal clk6, which has a phase inverse to the clock signal clk1, is used. Thus, the invalid pulse A can be removed by using a clock signal having an inverse phase. In this manner, a shaped phase comparison result 108 is obtained.

FIG. 3 is a timing chart showing an example of the relationship between an invalid pulse generated within the clock regeneration circuit according to the exemplary embodiment of the present invention and clocks for filtering. FIG. 3 shows the phase of the clock (0-9, 0), the first clock signal clk0, serial data 101, judgment results 105 (D0, D1, D2), phase comparison results 106 (dn0, up1), and clocks for filtering (c1k5, clk6).

As described above, since the judgment results 105 (D1) and (D2) change at different timing, an invalid pulse is generated in the phase comparison result 106 (up1). The invalid pulse is generated in an interval from the rising edge of the clock signal clk1 to the rising edge of the clock signal clk2. The actual timing of generation of an invalid pulse shifts rightward from the timing between the clock signals clk1 and clk2 because of an influence of a delay of circuit elements. In the exemplary embodiment, the invalid pulse is removed by using the clock signal clk6 as the clock for filtering the phase comparison result 106 (up1). With use of the clock signal clk6, if the timing of generation of an invalid pulse should shift rightward, it can be seen that the circuit can operate with a sufficient margin. Thus, an invalid pulse is removed by using the clock signal clk6, which has a phase inverse to the clock signal clk1 of the clock signals clk1 and clk2, which are used to sample the judgment results 105 (D1) and (D2).

The serial data 101 to the clock regeneration circuit according to the exemplary embodiment of the present invention are inputted to the phase comparator circuit 103, which operates with the 10-phase clocks 102. The serial data 101 are sampled by the judgment circuits 104 in the phase comparator circuit 103 and converted into judgment results 105. A phase comparison of the serial data 101 and the 10-phase clocks 102 is performed based upon the judgment results 105. The results are inputted as phase comparison results 106 to the pulse filter 107. The pulse filter 107 shapes the phase comparison results 106 with the 10-phase clocks 102 and outputs shaped phase comparison results 108 to the subsequent charge pumps 109. The charge pumps 109 control the VCO control voltage 110 based upon the shaped phase comparison results 108 for thereby controlling the phase of the 10-phase clocks 102 generated in the VCO 111. With the configuration of the present exemplary embodiment, the VCO control voltage 110 is controlled directly by using the phase comparison results. Therefore, no logical operations to the phase comparison results are required, and the VCO 111 can be controlled at a high speed.

According to the exemplary embodiment of the present invention, there is provided a clock regeneration circuit that can operate at a high speed with multi-phase clocks and does not cause deterioration of the performance of a feedback control that would be caused by logical operations to phase comparison results. While the invention has been particularly shown and described with reference to the exemplary embodiment thereof, the invention is not limited to the exemplary embodiment. It will be understood by those of ordinary skill in the art that various changes in form and details may be made therein without departing from the sprit and scope of this invention as defined by the claims.

### DESCRIPTION OF REFERENCE NUMERALS

101 serial data

102 10-phase clock

103 phase comparator circuit

104 judgment circuit

105 judgment result

106 phase comparison result

107 pulse filter

108 shaped phase comparison result

109 charge pump

110 VCO control voltage

111 VCO

1. A clock regeneration circuit characterized in that a phase comparison result of serial data being inputted and a clock signal is shaped with use of the clock signal or another clock signal having a predetermined phase difference from the clock signal, and a phase of the clock signal is controlled with use of the shaped phase comparison result.

2. The clock regeneration circuit according to claim 1, characterized in that the phase comparison result is obtained by an exclusive-OR operation of judgment results outputted from a plurality of judgment circuits that operate with multi-phase clocks.

3. The clock regeneration circuit according to claim 2, characterized in that the phase comparison result is obtained by an exclusive-OR operation of judgment results outputted from a plurality of judgment circuits that operate with clock signals having adjacent phase differences.

4. The clock regeneration circuit according to claim 1, characterized in that the shaping of the phase comparison result is conducted by an AND operation with the clock signal.

5. The clock regeneration circuit according to claim 4, characterized in that the clock signal used for shaping the phase comparison result has a phase inverse to a clock signal used for sampling a signal subjected to the phase comparison.

6. The clock regeneration circuit according to claim 1, characterized in that the clock signal is supplied from an oscillation circuit controlled by charge pumps that operate in parallel to each other.

7. A clock regeneration circuit characterized by comprising:
a judgment circuit operable to sample serial data into judgment data with multi-phase clock signals;
exclusive-OR circuits operable to compare judgment data that have been sampled with clock signals having adjacent phases to each other and output phase comparison results;
AND circuits operable to shape the phase comparison results;
a charge pump circuit operable to output a control voltage, the shaped phase comparison results being inputted to the charge pump circuit; and
a voltage controlled oscillator controlled by the control voltage so as to output the multi-phase clocks.

8. The clock regeneration circuit as recited in claim 7, characterized in that the phase comparison results being inputted are shaped in the AND circuits with use of a clock signal having a phase inverse to a clock signal used for sampling a signal that has been subjected to the phase comparison in the phase comparison results.

9. A clock regeneration method characterized by:
converting serial data being inputted into judgment data that are sampled with multi-phase clock signals having predetermined phase differences;
obtaining phase comparison results from an exclusive-OR operation of the judgment data that have been sampled with clock signals having adjacent phase differences;
shaping the phase comparison results with use of a clock signal having a phase inverse to a multi-phase clock signal used to sample the judgment data that have been compared in the phase comparison results; and
controlling a phase of the multi-phase clock signals with use of the shaped phase comparison results.

10. The clock regeneration circuit according to claim 2, characterized in that the clock signal is supplied from an oscillation circuit controlled by charge pumps that operate in parallel to each other.
